(19) United States
(12) Patent Application Publication
(10) Pub. No.: US 2014/0283906 A1
(43) Pub. Date: Sep. 25, 2014

(54) SYSTEM AND METHOD FOR CONTROLLING AN INVERSION LAYER IN A PHOTOVOLTAIC DEVICE

(71) Applicant: California Institute of Technology, Pasadena, CA (US)

(72) Inventors: Harry A. Atwater, South Pasadena, CA (US); Michael Deceglie, Golden, CO (US)

(21) Appl. No.: 14/222,540

(22) Filed: Mar. 21, 2014

Related U.S. Application Data
(60) Provisional application No. 61/804,047, filed on Mar. 21, 2013.

(51) Int. Cl. H01L 31/0224

(52) U.S. Cl. CPC H01L 31/022425; H01L 31/022475; H01L 31/022483
USPC 136/256

(57) ABSTRACT

A semiconductor photovoltaic device with an absorber layer for absorbing incident light, and a light transmitting layer located on the semiconductor body. The light transmitting layer induces an inversion layer in the semiconductor body and the current collected at the inversion layer is transported to a conductive electrode spaced from the light transmitting layer on the semiconductor body.

### CROSS-REFERENCE TO RELATED APPLICATION(S)

The present application claims priority to U.S. Provisional Patent Application No. 61/804,047 filed on Mar. 21, 2013, which is incorporated herein by reference in its entirety.

### STATEMENT REGARDING FEDERALLY SPONSORED RESEARCH OR DEVELOPMENT

This invention was made with government support under DE-EE0005311/T-106288 awarded by the Department of Energy. The government has certain rights in the invention.

### FIELD

The present disclosure relates to photovoltaic cells. More particularly, it relates to a system and method for controlling an inversion layer in a photovoltaic device.

### BACKGROUND

Semiconductor photovoltaic devices generate electron-hole pairs (i.e., charges or carriers) due to incident photons being absorbed in the semiconductor substrate. In these types of photovoltaic devices, carriers are extracted out of an absorber layer and then transported laterally along a transparent conductor, a conductive grid, or a heavily doped semiconductor emitter to electrical contacts located at an edge of the photovoltaic device. However, such structures often are not sufficient to efficiently collect current at the electrical contacts.

### SUMMARY

In the invention, an inversion layer is provided at the surface of a photovoltaic absorber to provide a lateral conductive path for generated charge carriers to electrodes located at an edge of the absorber. The inversion layer is created by an inversion inducing layer which may be an insulated gate layer or a layer forming a heterojunction with the absorber.

According to a first aspect, a photovoltaic device described, including: a semiconductor body having an absorber layer for absorbing incident light; a light transmitting layer on the semiconductor body, the light transmitting layer configured to induce an inversion layer in the semiconductor body; and a conductive electrode spaced from the light transmitting layer on the semiconductor body and configured to collect current from the inversion layer.

The device may include a biasing circuit for applying a bias across the light transmitting layer and the semiconductor body, wherein the inversion layer is induced in response to the bias.

The device may include a heterojunction formed by the light transmitting layer on the semiconductor body, wherein the inversion layer is induced as a consequence of the heterojunction.

The light transmitting layer may be an insulated gate layer, the insulated gate layer including a transparent conductor and a dielectric.

A conductivity of the inversion layer in the semiconductor body may be higher than the conductivity of the absorber layer in the semiconductor body.

The inversion layer may be within and at a surface of the semiconductor body.

The light may be able to pass through the light transmitting layer and the inversion layer.

According to a second aspect, a method for generating photovoltaic power is described, the method including: inducing an inversion layer in a semiconductor body with a light transmitting layer on the semiconductor body; generating current by applying incident light to an absorber layer of the semiconductor body; and collecting the current from the inversion layer with a conductive electrode spaced from the light transmitting layer.

The method may include applying a bias to the light transmitting layer, wherein the inversion layer is induced by the light transmitting layer in response to the applied bias.

The inversion layer may be induced by the light transmitting layer as a consequence of a heterojunction by the light transmitting layer and the semiconductor body.

### BRIEF DESCRIPTION OF THE DRAWINGS

A more complete appreciation of the present invention, and many of the attendant features and aspects thereof, will become more readily apparent as the invention becomes better understood by reference to the following detailed description when considered in conjunction with the accompanying drawings in which like reference symbols indicate like components.

FIG. 1 is a schematic cross-sectional view of a photovoltaic device according to an embodiment of the invention.

FIG. 2 is a schematic cross-sectional view of the photovoltaic device according to another embodiment of the invention.

FIG. 3 is a cross-sectional view of an insulated gate layer according to an embodiment of the present invention.

FIGS. 4A-4B are graphical representations of two specific fill factors of photovoltaic devices constructed according to the invention.

### DETAILED DESCRIPTION

The present invention will now be described more fully with reference to the accompanying drawings, in which example embodiments thereof are shown. While the described embodiments of the invention may be modified in various ways, the described embodiments are presented as examples in the drawings and in the detailed description below. The intention of the disclosure, however, is not to limit the invention to the particular embodiments described. To the contrary, the invention is intended to cover all modifications, equivalents, and alternatives falling within the scope of the invention as defined by the appended claims. Moreover, detailed descriptions related to well-known functions or configurations have been omitted in order not to unnecessarily obscure the subject matter of the present invention.

The sizes of the layers and regions in the drawings may be exaggerated for convenience of explanation. Like reference numerals refer to like elements throughout. It will be understood that when a layer, region, or component is referred to as being “on”, “formed on”, “over”, or “formed over”, another layer, region, or component, it can be directly or indirectly on or formed on the other layer, region, or component. That is, for example, intervening layers, regions, or components may be present.

In semiconductor photovoltaic devices, a portion of a semiconductor body near a light-incident surface may be doped with carriers of opposite charge of majority carriers in the absorber to create a region that has a conductivity higher than the rest of the semiconductor body. A junction in the semiconductor also provides a built-in electric field that serves to separate photo-generated electron-hole pairs. This higher conductivity region then permits separated charge carriers to be transported laterally to electrical contact(s) where the charge carriers are used to power external loads (e.g., electronic devices). Alternatively, a transparent conductor can be placed at or near the surface of the semiconductor body to create a region having a conductivity higher than the rest of the semiconductor body. However, mobility of charge carriers within such a doped region or transparent conductor are relatively low (e.g., tens of cm² s⁻¹ or less). Thus, it is desirable in a photovoltaic device to provide a highly conductive current collecting layer with high mobility (e.g., hundreds of cm² s⁻¹ or more). Furthermore, in some material systems, it can be difficult or nearly impossible to create a charge collecting junction. Even if one can be created, neither layer may be conductive enough to provide low-loss charge collection. In these cases, charges can alternatively be collected by an inversion layer at a surface of the device. However, transport (of the carriers) in these inversion layers can be relatively poor. Thus, it is desirable in a photovoltaic device utilizing an inversion layer collector to optimize the inversion layer and its associated interface for lateral current flow.

In one embodiment, the photovoltaic device of the invention has a transparent, highly conductive layer with high mobility at its upper surface. This is accomplished by creating an inversion layer along an upper portion of a semiconductor body, or in a region near the surface. According to the embodiment, the inversion layer is formed within the semiconductor substrate but is located near its upper surface. An inversion layer is defined herein as a region in a semiconductor where the majority carrier type changes from one type to the other (e.g., from electrons to holes, or from holes to electrons) due to semiconductor band-bending rather than doping in the region. The portion of the semiconductor substrate below the inversion layer is the absorber layer.

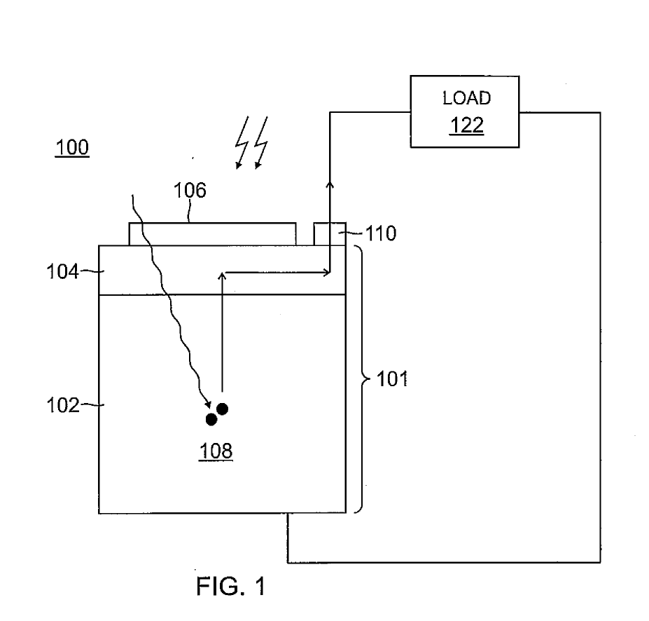

FIG. 1 is a schematic cross-sectional view of a photovoltaic device showing an exemplary structure for forming a highly conductive layer in a semiconductor substrate 101 by inducing an inversion layer 104. The photovoltaic device may comprise a semiconductor body 101 or other region of a single conductivity type (e.g., n-type or p-type) or a semiconductor having a junction. An inversion layer 104 is formed near the upper surface of the semiconductor substrate 101 by inducing a field within the semiconductor body 101. Thus, the inversion layer 104 is created wholly within the semiconductor body 101. That is, the inversion layer 104 is a part of the semiconductor substrate 101, and is not separate from it, or located on the semiconductor body 101. Instead, the inversion layer 104 of the illustrated embodiment is formed by an induced field that is applied along an upper portion of the semiconductor body 101 by an inversion inducing layer 106 at the surface of the semiconductor body 101. The remaining (lower) portion of the semiconductor body 101, in which inversion is not induced, is the absorber layer 102, which is used to generate electron-hole pairs 108 when a photon of incident light is absorbed therein. The inversion inducing layer 106 may also be referred to herein as a light transmitting layer. In some embodiments, a heterojunction is formed at an interface of the inversion inducing layer 106 and the semiconductor substrate 101. Examples of a heterojunction forming inversion inducing layer 106 can include, silicon nitride, silicon carbide, and other dielectric materials that have a high charge density. A person skilled in the art would understand that such heterojunction inherently causes the inversion layer 104 to be formed at the semiconductor substrate 101

Thus, an inversion layer 104 having a higher conductivity, relative to the conductivity of the absorber layer 102, is formed in the semiconductor substrate 101. Therefore, when a photon (i.e., light ray) incident on the photovoltaic device 100 is transmitted through the inversion inducing layer 106 and is absorbed by the absorber layer 102, an electron-hole pair 108 is generated and released. In order for the incident photon to pass through the inversion inducing layer 106, the inversion inducing layer 106 should be transparent.

In some embodiments, an electrical contact 110 (or a conductive electrode) is formed on the semiconductor substrate 101 and coupled to the inversion layer 104. Thus, the charge 108 generated and released from the absorber layer 102 is transported toward the electrical contact 110 via the highly conductive inversion layer 104. The electrical contact 110 is electrically coupled to an external device or circuit that makes use of the generated electric charge 108. For example, the electrical contact can be a conductive bus bar or a metal layer that is connected to external load(s) 122 such as, for example, a battery charging circuit, but is spaced from the inversion inducing layer 106.

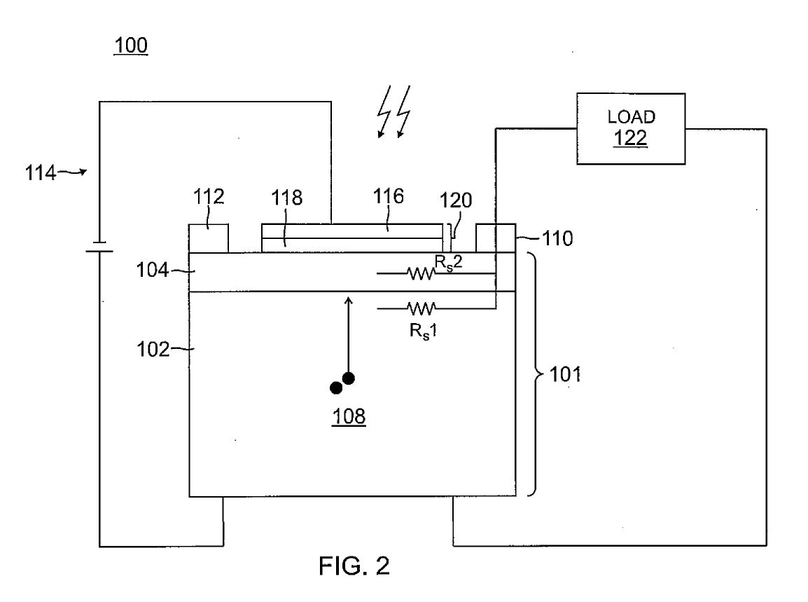

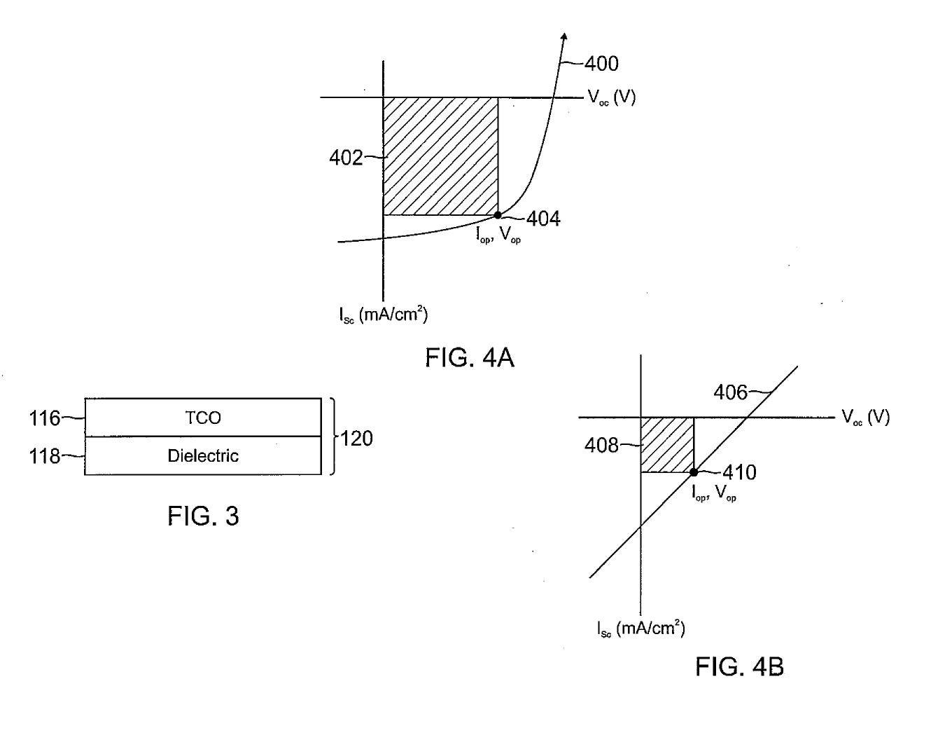

In some embodiments, the inversion inducing layer 106 is an insulated gate layer 120, as shown in FIG. 2. The gate layer 120 is similar to a gate of a commercially available metal oxide semiconductor field effect transistor (MOSFET). As shown in FIGS. 2-3, the insulated gate layer 120 is located on the semiconductor body 101 and comprises a transparent conductor (e.g., transparent conductive oxide (TCO) 116) formed on a dielectric layer 118. According to an embodiment, the dielectric layer 118 is formed between the gate layer 116 and the semiconductor substrate 101.

In some embodiments, a bias circuit 114 is coupled to the photovoltaic device 100. The bias circuit 114 is configured to bias the insulated gate layer 120 to induce the inversion layer 104. A first electrode of the bias circuit 114 is electrically coupled to the gate layer 116 and a second electrode is electrically coupled to the semiconductor body 101. Therefore, a bias (e.g., a voltage) can be applied by the bias circuit 114 across the gate layer 116 and the semiconductor body 101, to induce an inversion layer 104 along an upper surface of the semiconductor body 101. Because the gate layer 116 is insulated from the semiconductor body 101 by the dielectric layer 118, appreciable current does not flow from the biasing circuit 114 through the photovoltaic device 100. Thus, no power is consumed by the biasing circuit 114.

In a manner similar to the embodiment described with reference to FIG. 1, the generated electric charge 108 is collected at the inversion layer 104 and is transported to the electrical contact 110 in the inversion layer 104 primarily by diffusion. The electric charge 108 traverses the inversion layer 104 and not in the absorber layer 102 because the conductivity of the inversion layer 104 is much higher relative to the absorber layer 102.

FIG. 2 illustrates the relative conductivity of the absorber layer 102 and the inversion layer 104. In some embodiments, the absorber layer 102 has an inherent resistance, shown schematically in FIG. 2 as Rs1. The induced inversion layer 104 also has an inherent resistance, shown schematically in FIG. 2 as Rs2, but the inherent resistance of the inversion layer 104 is much lower than the resistance Rs1 of the absorber layer 102. The inherent resistances Rs1 and Rs2 can be conceptually represented as two resistors in parallel. In some embodiments, because Rs1>>Rs2, the photo-generated electric charge 108 is collected at or near the surface of the semiconductor body 101 flows laterally within the inversion layer 104. For example, resistance Rs1 may be about 1 to 100Ω cm, whereas resistance Rs2 may be about 10⁻³ to 10⁻²Ω cm. While resistors are used to conceptually illustrate the resistances through the inversion layer 104 and/or the absorber layer 102, the actual resistances depend on various factors such as, for example, the geometry of the device.

In the case where there is no junction other than the junction established by the inversion inducing layer 106, the charges are collected at the front of the cell (i.e., near the electrical contact 110) due to an electric field associated with the inversion layer 104. The transport in the inversion layer 104 is efficient and low-loss once the charges are there. If the inversion layer approach is used with another junction, the field of the pn junction may separate the charges, in which case the inversion layer serves for lateral conduction.

In some embodiments, two electrical contacts 110, 112 are on the semiconductor substrate 101 and the distance between them is about 0.1 mm to about 1 mm. In some embodiments, a thickness of the semiconductor body 101 is about 1 μm. However, in some embodiments, the thickness of the semiconductor body 101 may be hundreds of μm, depending on the type of semiconductor material. In some embodiments, the electrical contacts can be coupled to the inversion layer 104 through openings in the insulated gate layer 120.

FIG. 3 is a cross-sectional view of the insulated gate layer 120. In some embodiments, the transparent conducting layer 116 can comprise, for example, graphene, indium tin oxide, aluminum doped zinc oxide, or heterogeneous transparent conductors such as silver nanowires in a non-conducting matrix, and the dielectric layer 118 can comprise, for example, silicon nitride, aluminum oxide, nickel oxide, or silicon oxide.

Therefore, according to an embodiment of the invention, when photons from a light source (e.g., sun) are incident on the photovoltaic device 100, the photons pass through the transparent insulated gate layer 120 and into the absorber layer 102 where they are absorbed to create electron-hole pairs 108. These charge carriers are collected by the circuit including the inversion layer 104. Because the conductivity of the inversion layer 104 is much higher than the conductivity of the absorber layer 102, the charge 108 is transported primarily through the inversion layer 104 to the electric contacts 110, 112.

FIGS. 4A-4B are graphical representations of the fill factor of photovoltaic devices constructed according to the invention. FIG. 4A shows a theoretical fill factor of about 80%, which is the case when the inversion layer 104 is used, and FIG. 4B shows a theoretical fill factor of about 25% in absence of an inversion layer (i.e., when the resistance of the path along which the carriers are transported is high). According to an embodiment of the present invention, FIG. 4A shows the open circuit voltage (V_{OC}) vs. short circuit current (I_{SC}) with a curved line 400. The shaded region 402 under the curve indicates the fill factor, which is an amount of power that is generated by the photovoltaic device, equivalent to the product of V_{OC} and I_{SC} 404. In the case shown in FIG. 4B when the inversion layer 104 of the invention is not used, the open circuit voltage (V_{OC}) vs. short circuit current (I_{SC}) of the photovoltaic device is represented by a linear line 406. Accordingly, the shaded region 408 indicates a much smaller theoretical fill factor, which is equivalent to the product of V_{OC} and I_{SC} 410. Therefore, much more power can be generated from the photovoltaic device having the low resistance inversion layer 104, as indicated in graph of FIG. 4A.

According to an embodiment of the present invention, an interface of the inversion inducing layer is optimized to improve conductivity of the inversion layer in order to improve transport of the generated electron-hole pair from the absorber layer to the electrical contacts. For example, the atomic and/or chemical structures of the interface properties can be tuned to achieve such optimization, including effective passivation of the interface and associated trap states. This can be achieved with carefully tuned layer deposition processing or chemical surface treatments.

Although the terms “first”, “second”, etc. may be used herein to describe various components, these components should not be limited by these terms. These descriptors are used only to distinguish one component from another. The terminology in this application is used to more clearly describe the presented embodiments and is not intended to limit the scope of the present invention.

As used herein, the singular forms “a”, “an”, and “the” are intended to include the plural forms as well, unless the context clearly indicates otherwise. It will be further understood that the terms “comprises” and/or “comprising”, as used herein, specify the presence of the stated features or components, but do not preclude the presence or addition of one or more other features or components. “/”, as used herein may be interpreted as “and”, or may be interpreted as “or” depending on the situation.

It will be recognized by those skilled in the art that various modifications may be made to the illustrated and other embodiments of the invention described above, without departing from the broad inventive step thereof. Therefore, the invention is not limited to the particular embodiments or arrangements disclosed, but is rather intended to cover any changes, adaptations or modifications which are within the scope and spirit of the invention as defined by the appended claims and their equivalents.

1. A photovoltaic device, comprising:
a semiconductor body having an absorber layer for absorbing incident light;
a light transmitting layer on the semiconductor body, the light transmitting layer configured to induce an inversion layer in the semiconductor body; and
a conductive electrode spaced from the light transmitting layer on the semiconductor body and configured to collect current from the inversion layer.

2. The device of claim 1, further comprising a biasing circuit for applying a bias across the light transmitting layer and the semiconductor body, wherein the inversion layer is induced in response to the bias.

3. The device of claim 2, wherein substantially no current flows from the biasing circuit to the light transmitting layer.

4. The device of claim 2, wherein the biasing circuit comprises external control circuitry.

5. The device of claim 1, further comprising a heterojunction formed by the light transmitting layer on the semiconductor body, wherein the inversion layer is induced as a consequence of the heterojunction.

6. The device of claim 1, wherein the light transmitting layer is an insulated gate layer, the insulated gate layer comprising a transparent conductor and a dielectric.

7. The device of claim 6, wherein the transparent conductor is selected from the group consisting of: graphene, heterogeneous transparent conductors, indium tin oxide, and aluminum doped zinc oxide, and other conducting oxides.

8. The device of claim 6, wherein the dielectric is selected from the group consisting of: aluminum oxide, nickel oxide, silicon oxide, and silicon nitride.

9. The device of claim 1, wherein a conductivity of the inversion layer in the semiconductor body is higher than the conductivity of the absorber layer in the semiconductor body.

10. The device of claim 1, wherein the inversion layer is within and at a surface of the semiconductor body.

11. The device of claim 1, wherein incident light passes through the light transmitting layer and the inversion layer.

12. The device of claim 1, wherein the inversion layer is less than 1% of an entire thickness of the semiconductor body.

13. A method for generating photovoltaic power, the method comprising:
inducing an inversion layer in a semiconductor body with a light transmitting layer on the semiconductor body;
generating current by applying incident light to an absorber layer of the semiconductor body; and
collecting the current from the inversion layer with a conductive electrode spaced from the light transmitting layer.

14. The method of claim 13, applying a bias to the light transmitting layer, wherein the inversion layer is induced by the light transmitting layer in response to the applied bias.

15. The method of claim 13, wherein the inversion layer is induced by the light transmitting layer as a consequence of a heterojunction by the light transmitting layer and the semiconductor body.

16. The method of claim 13, wherein the inversion layer is within and at a surface of the semiconductor body.

17. The method of claim 13, wherein the light transmitting layer is an insulated gate layer comprising a transparent conductor and a dielectric.

18. The method of claim 13, wherein a conductivity of the inversion layer in the semiconductor body is higher than a conductivity of the absorber layer in the semiconductor body.

19. The method of claim 13, wherein the inversion layer is less than 1% of an entire thickness of the semiconductor body.
